(19) United States
(12) Patent Application Publication
(10) Pub. No.: US 2025/0005214 A1
(43) Pub. Date: Jan. 2, 2025

(54) SYSTEMS AND METHODS FOR INTELLIGENTLY DESIGNING AND RECONFIGURING DATA CENTERS

(71) Applicant: Nvidia Corporation, Santa Clara, CA (US)

(72) Inventors: Siddha Ganju, Santa Clara, CA (US); Aastha Jhunjhunwala, Santa Clara, CA (US); Elad Mentovich, Tel Aviv (IL); Ryan Albright, Beaverton, OR (US); Srikanth Cherukuri, Santa Clara, CA (US)

(21) Appl. No.: 18/215,290

(22) Filed: Jun. 28, 2023

(51) Int. Cl. G06F 30/13; G06F 30/27

(52) U.S. Cl. CPC G06F 30/13; G06F 30/27

(57) ABSTRACT

Systems, computer program products, and methods are described herein for intelligent intelligently designing and reconfiguring data centers. For example, a system may be an artificial-intelligence-based system for designing and reconfiguring data centers based on user inquiries. The system may receive inquiries from users requesting a design for a data center having particular performance characteristics (e.g., selected performance characteristics), changes to an existing design of a data center, information about a data center, and/or the like. The inquiries may be text-based or audio and in the form of natural language questions or commands. The system may use two machine learning models, namely a knowledge base model and a ranking model. The system may use the knowledge base model to determine solutions to user inquiries and then use the ranking model to determine rankings for the solutions.

### FIELD OF THE INVENTION

The present invention relates to systems and methods for intelligently designing and reconfiguring data centers.

### BACKGROUND

Technical experts (e.g., data center designers), may receive inquiries from users about data centers, such as requests to design new data centers, requests to change the designs of existing data centers, questions regarding data centers, and/or the like. To answer these inquiries, the technical experts must access various systems and databases for information to research and identify solutions to the inquiries.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a system for designing a data center. The system may include a display device configured to display a graphical user interface, an input device configured to receive user input, a first machine learning model configured to determine solutions to inquiries regarding data centers, and a second machine learning model configured to determine rankings for solutions to inquiries regarding data centers. The system may also include a non-transitory storage device including computer executable program code and a processor in communication with the display device, the input device, the first machine learning model, the second machine learning model, and the non-transitory storage device. The computer-executable program code may include instructions configured to cause the processor to perform operations including receiving, from the input device, an inquiry associated with a data center based on the user input and determining, using the first machine learning model, solutions to the inquiry. The computer-executable program code may include instructions configured to cause the processor to perform operations including determining, using the second machine learning model, a ranking for each of the solutions to the inquiry and causing the display device to display the solutions to the inquiry via the graphical user interface in an order corresponding to the rankings.

In some embodiments, the computer-executable program code may include instructions configured to cause the processor to perform operations including receiving, from the input device, selection of a first solution of the solutions and causing, in response to receiving the selection of the first solution, the display device to display a virtual performance of the first solution in a three-dimensional representation of the data center.

In some embodiments, the inquiry may include a question about the data center.

In some embodiments, the inquiry may include a request to change a configuration of the data center. Additionally, or alternatively, the computer-executable program code may include instructions configured to cause the processor to perform operations including, in determining the solutions to the inquiry, determining one or more processes for changing the configuration of the data center, in determining the rankings for the solutions to the inquiry, determining, for each process of the one or more processes, a number of steps required to perform the respective process, and adjusting the graphical user interface to include the one or more processes in the order based on the number of steps required to perform each process of the one or more processes. In some embodiments, the computer-executable program code may include instructions configured to cause the processor to perform operations including receiving, from the input device, selection of a first process of the one or more processes, where the first process includes a series of steps and causing, in response to receiving the selection of the first process, the display device to display virtual performances of each step in the series of steps in a three-dimensional representation of the data center. Additionally, or alternatively, the computer-executable program code may include instructions configured to cause the processor to perform operations including receiving, from the input device, selection of a first process of the one or more processes, where the first process includes a series of steps and causing, in response to receiving the selection of the first process, the display device to display virtual performances of each step in the series of steps in a three-dimensional representation of the data center.

In some embodiments, the inquiry may include a text inquiry and/or an audio inquiry.

In some embodiments, the computer-executable program code may include instructions configured to cause the processor to perform operations including, before determining the solutions to the inquiry (i) identifying keywords in the inquiry and (ii) determining, based on the identified keywords, an intent of the inquiry and, in determining the solutions to the inquiry, determining the solutions to the inquiry based on the identified keywords and the intent of the inquiry.

In some embodiments, the inquiry may include performance characteristics, and the computer-executable program code may include instructions configured to cause the processor to perform operations including, in determining the solutions to the inquiry, determining configurations of equipment in the data center having the performance characteristics, in determining the rankings for the solutions to the inquiry, determining, for each configuration of the configurations, a preference rating for the respective configuration based on historical user preference data, and, in causing the display device to display the solutions to the inquiry, causing the display device to display the configurations in the order based on the preference rating for each configuration of the configurations. Additionally, or alternatively, the inquiry may be a first inquiry, and the computer-executable program code may include instructions configured to cause the processor to perform operations including, after causing the display device to display the graphical user interface, receiving, from the input device, a selection of a first configuration of the configurations and a second inquiry including (i) a size of the data center and (ii) a request for a materials list and associated floor plan implementing the first configuration, determining, using the first machine learning model, a plurality of materials lists and associated floor plans implementing the first configuration in the data center corresponding to the size, determining, using the second machine learning model and for each materials list and associated floor plan of the plurality of materials lists and associated floor plans, a preference rating for the respective materials list and associated floor plan, and causing the display device to display the plurality of materials lists and associated floor plans in another order based on the preference rating for each respective materials list and associated floor plan. In some embodiments, the selection may be a first selection, and the computer-executable program code may include instructions configured to cause the processor to perform operations including, after causing the display device to display the plurality of materials lists and associated floor plans, receiving, from the input device, a second selection of a first materials list and an associated first floor plan of the plurality of materials lists and associated floor plans and causing, in response to receiving the second selection, the display device to display a three-dimensional representation of the data center having the first floor plan.

In some embodiments, the first machine learning model may be a supervised model trained using rule data including rules for configuring data centers, historical solution data including historical configurations of data centers developed for customers based on customer requirements, and historical action data including historical actions performed on data centers and historical outcomes of the historical actions. Additionally, or alternatively, the computer-executable program code may include instructions configured to cause the processor to perform operations including providing retraining data to another system for retraining the first machine learning model, where the retraining data includes inquiries received from the input device and outcomes associated with the inquiries.

In some embodiments, the second machine learning model may be a supervised model trained using historical action data including historical actions performed on data centers and historical outcomes of the historical actions. Additionally, or alternatively, the computer-executable program code may include instructions configured to cause the processor to perform operations including providing retraining data to another system for retraining the second machine learning model, where the retraining data includes inquiries received from the input device and outcomes associated with the inquiries.

In another aspect, the present invention is directed to a computer program product for designing a data center that includes a non-transitory computer-readable medium including code. The code, when executed by a first apparatus, may cause the first apparatus to receive, using an input device of the first apparatus, input from a user including an inquiry associated with a data center, determine, using a first machine learning model, solutions to the inquiry, where the first machine learning model is configured to determine solutions to inquiries regarding data centers, and determine, using a second machine learning model, rankings for the solutions to the inquiry by determining for each solution of the solutions a respective ranking, where the second machine learning model is configured to determine rankings for solutions to inquiries regarding data centers. The code, when executed by a first apparatus, may cause the first apparatus to display, using a display device of the first apparatus, a graphical user interface including the solutions to the inquiry in an order corresponding to the rankings, receive, using the input device, input from the user selecting a first solution of the solutions, and display, in response to receiving the selection of the first solution and using the display device, a virtual performance of the first solution in a three-dimensional representation of the data center.

In some embodiments, the inquiry may include a question about the data center and/or a command to change a configuration of the data center.

In some embodiments, the inquiry may include a request to add cooling to a rack in the data center, and the non-transitory computer-readable medium may include code that, when executed by the first apparatus, causes the first apparatus to, in determining the solutions to the inquiry, determine one or more processes for adding cooling to the rack in the data center, in determining the rankings for the solutions to the inquiry, determine, for each process of the one or more processes, a number of steps required to perform the respective process and a cost associated with the respective process, and adjust the graphical user interface to include the one or more processes in the order based on a combined rating based on the number of steps required to perform each process and the cost associated with each process.

In some embodiments, the inquiry may include a request to move a hot aisle of the data center a user-specified distance in a direction, and the non-transitory computer-readable medium may include code that, when executed by the first apparatus, causes the first apparatus to, in determining the solutions to the inquiry, determine one or more processes for moving the hot aisle the user-specified distance in the direction within the data center, in determining the rankings for the solutions to the inquiry, determine, for each process of the one or more processes, a number of steps required to perform the respective process and a cost associated with the respective process, and adjust the graphical user interface to include the one or more processes in the order based on a combined rating based on the number of steps required to perform each process and the cost associated with each process.

In some embodiments, the inquiry may include a request to design the data center to have user-specified performance characteristics, and the non-transitory computer-readable medium may include code that, when executed by the first apparatus, causes the first apparatus to, in determining the solutions to the inquiry, determine one or more designs for the data center to achieve the selected performance characteristics, in determining the rankings for the solutions to the inquiry, determine, for each design of the one or more designs, a preference rating for the respective design based on historical user preference data, adjust the graphical user interface to include the one or more designs in the order based on the preference rating for each design of the one or more designs, in displaying the virtual performance of the first solution in a three-dimensional representation of the data center, display a user-navigable three-dimensional representation of the data center. receive, using the input device, navigation input from the user including navigation commands, and adjust, in response to receiving the navigation input and using the display device, the displayed user-navigable three-dimensional representation of the data center based on the navigation commands.

In another aspect, the present invention is directed to a method for designing a data center. The method may include receiving, using an input device, input from a user including a request to design a data center having selected performance characteristics, determining, using a first machine learning model, one or more designs for the data center to achieve the selected performance characteristics, where the first machine learning model is configured to determine solutions to inquiries regarding data centers, and determining, using a second machine learning model and for each design of the one or more designs, a preference rating for the respective design based on historical user preference data. The method may include displaying, using a display device, the one or more designs in order of the preference rating for each design of the one or more designs and receiving, using the input device, selection input from the user selecting a first design of the one or more designs. The method may include displaying, using the display device and in response to receiving the selection input, a user-navigable three-dimensional representation of the data center configured according to the first design, receiving, using the input device, navigation input from the user including navigation commands, and adjusting, in response to receiving the navigation input, the displayed user-navigable three-dimensional representation of the data center based on the navigation commands.

In some embodiments, the method may include, after receiving the selection input selecting the first design, receiving, using the input device, inquiry input from the user including a request for a materials list implementing the first design, determining, using the first machine learning model, a plurality of materials lists implementing the first design, determining, using the second machine learning model and for each materials list of the plurality of materials lists, a preference rating for the respective materials list, and displaying, using the display device, the plurality of materials lists in order of the preference rating for each materials list of the plurality of materials lists.

In some embodiments, the method may include receiving, from the input device, an inquiry associated with the data center, determining, using the first machine learning model, solutions to the inquiry, determining, using the second machine learning model, a ranking for each of the solutions to the inquiry, and causing the display device to display the solutions to the inquiry via a graphical user interface in an order corresponding to the rankings. Additionally, or alternatively, the method may include receiving, from the input device, selection of a first solution of the solutions and causing, in response to receiving the selection of the first solution, the display device to display a virtual performance of the first solution in the user-navigable three-dimensional representation of the data center. In some embodiments, the method may include, in determining the solutions to the inquiry, determining configurations of equipment in the data center having the performance characteristics, in determining the rankings for the solutions to the inquiry, determining, for each configuration of the configurations, a preference rating for the respective configuration based on historical user preference data, and, in causing the display device to display the solutions to the inquiry, causing the display device to display the configurations in the order based on the preference rating for each configuration of the configurations.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made to the accompanying drawings, wherein:

FIG. 1 illustrates a process flow for training a knowledge base machine learning model, in accordance with an embodiment of the invention;

FIG. 2 illustrates a process flow for training a ranking machine learning model, in accordance with an embodiment of the invention;

FIG. 3 illustrates a process flow for intelligently responding to a user inquiry regarding a data center, in accordance with an embodiment of the invention;

FIG. 4 illustrates another process flow for intelligently responding to a user inquiry regarding a data center, in accordance with an embodiment of the invention;

FIG. 5 illustrates a system environment for intelligently designing and reconfiguring data centers, in accordance with an embodiment of the invention; and

FIG. 6 is a diagram of example components of one or more devices, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). Like numbers refer to like elements throughout. No element, act, or instruction used herein should be construed as critical or essential unless explicitly described as such.

As noted, technical experts (e.g., data center designers), may receive inquiries from users about data centers, such as requests to design new data centers, requests to change the designs of existing data centers, questions regarding data centers, and/or the like. To answer these inquiries, the technical experts must search various databases, which may be located on different systems, for information to identify and develop solutions to the inquiries. For example, the technical experts may access and search databases of technical literature regarding data centers, specifications and/or parameters of previously designed data centers, and/or the like to identify solutions to the inquiries. However, such searching by the technical experts consumes resources (e.g., processing resources, memory resources, power resources, communication resources, network resources, and/or the like). Furthermore, the technical experts cannot access and search the databases quickly enough to provide answers to users in real time, much less answer follow-up inquiries in real time. Additionally, researching solutions to the inquiries consumes time of the technical experts, which not only could be spent developing new design center solutions but also consumes financial resources of the corporations employing the technical experts. Moreover, the technical experts may not have access to sufficient data to answer the inquiries, may make errors, and/or encounter other obstacles resulting in inferior or sub-optimal solutions to the inquiries, such as inferior data center designs, which consume additional resources (e.g., processing resources, memory resources, power resources, communication resources, network resources, and/or the like).

Some embodiments described herein provide a system, a computer program product, and/or a method for intelligently designing and reconfiguring data centers. For example, a system may be an artificial-intelligence-based system for designing and reconfiguring data centers based on user inquiries. The system may receive inquiries from users requesting a design for a data center having particular performance characteristics (e.g., selected performance characteristics, desired performance characteristics, performance characteristics to achieve desired results or output, and/or the like), changes to an existing design of a data center, information about a data center (e.g., how much cabling is in the data center, a size of the data center, performance capabilities of the data center, how many cooling units are in the data center), and/or the like. The inquiries may be text-based or audio and in the form of natural language questions or commands. The system may use two machine learning models, namely a knowledge base model and a ranking model. The knowledge base model may be trained to determine possible solutions (e.g., answers) to inquiries based on data including ground rules, such has how cabling and cooling systems must be implemented, how much space a rack occupies, and/or the like, as well as data compiled from whitepapers regarding data centers, data center solutions previously developed for customers and their results, and/or the like. The ranking model may be trained to rank solutions output by the knowledge base model based on data including how many steps are required to implement the solutions, solutions historically preferred by users, solutions that include more keywords, solutions having better performance metrics, and/or the like. The system may thus use the knowledge base model to determine solutions to user inquiries and then use the ranking model to determine rankings for the solutions. The system may then display the solutions to the user based on the rankings. The system may then receive further inquiries about the solutions, which the system may then answer using the knowledge base model and ranking model. Additionally, or alternatively, the system may receive input from the user selecting one of the solutions and display, for example, a virtual performance of the solution in a three-dimensional representation of the data center (e.g., a metaverse rendering of the data center and its equipment). In this way, the system may receive a variety of inquiries from users that would typically be received by technical experts, process the inquiries in real time, and provide solutions to the inquiries as well as to any follow-up questions the users may have. By using the knowledge base model and the ranking model, the system can conserve resources (e.g., processing resources, memory resources, power resources, communication resources, network resources, and/or the like) that would otherwise be consumed by technical experts researching the answers to the inquiries. Additionally, by displaying virtual performances of the solutions to the user, a non-expert user may be capable of executing the identified solution without assistance from a technical expert. Furthermore, by using the knowledge base model and the ranking model, the system may provide the user with data center designs having optimized performance characteristics for a given application, which conserves resources that would otherwise be consumed by inferior data center designs and which a technical expert may not be capable of designing given limited time and access to data.

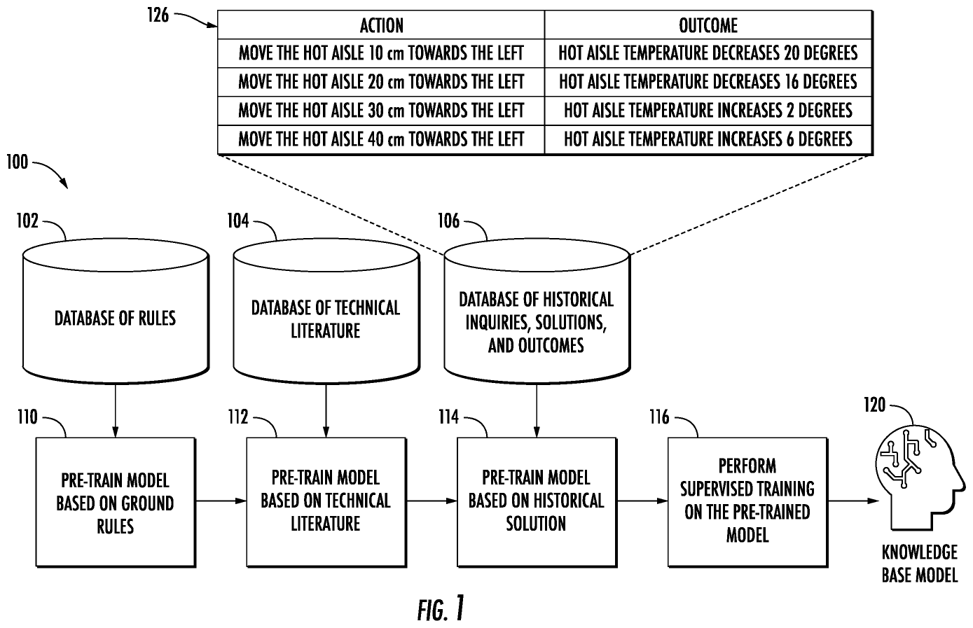

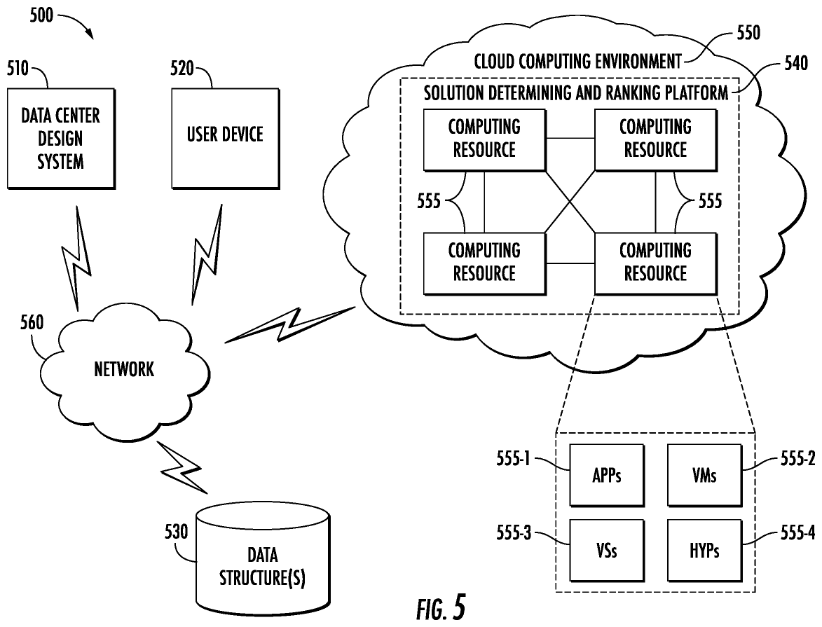

FIG. 1 illustrates a process flow 100 for training a knowledge base model 120 (e.g., one or more machine learning models), in accordance with an embodiment of the invention. In some embodiments, one or more data center design systems (e.g., similar to the data center design system described herein with respect to FIG. 5), one or more solution determining and ranking platforms (e.g., similar to the solution determining and ranking platform described herein with respect to FIG. 5), and/or the like may perform one or more of the steps of the process flow 100. In some embodiments, the knowledge base model 120 may be configured (e.g., by the training) to determine solutions to inquiries regarding data centers.

As shown in block 110, the process flow 100 may include pre-training a model based on data from a database of rules 102. In some embodiments, the database of rules 102 may include a data structure (e.g., a database, an array, a linked list, a record, a hash table, and/or the like) that includes data associated with physical attributes of data centers, such has how cabling and cooling systems must be implemented, how much space a rack occupies, material contents of components of data centers (e.g., racks, cooling equipment, computing equipment, cabling, and/or the like), dimensions of components of data centers, settings of components of data centers (e.g., fan speeds), power consumption of components of data centers, capacities of power cables, optimal operating values for components of data centers (e.g., operating temperatures), cable types, cable ends, temperatures of processing units, types of interconnects and cabling, types of graphical process unit and central processing unit combinations, manufacturing information of processing units and components of data centers, types of cooling mechanisms (e.g., fans, liquids, and/or the like), topology of data centers, access to storage, physical configuration information, correlations between physical attributes and performance capabilities, design standards, practitioner guidelines, and/or the like. Pre-training the model based on the ground rules may thus configure the knowledge base model 120 to be able to make decisions regarding physical configurations of data centers based on certain user inputs received, as described below.

As shown in block 112, the process flow 100 may include pre-training the model based on data from a database of technical literature 104. In some embodiments, the database of technical literature 104 may include a data structure (e.g., a database, an array, a linked list, a record, a hash table, and/or the like) that includes data compiled from technical literature regarding data centers, such as whitepapers, user manuals, frequently-asked-questions documents, specification and/or data sheets for components of data centers, websites providing information regarding components of data centers, videos providing information regarding components of data centers, and/or the like. Pre-training the model based on the technical literature may configure the knowledge base model 120 to be able to make decisions regarding technical configurations of data centers (e.g., such that the data centers function properly).

As shown in block 114, the process flow 100 may include pre-training the model based on data from a database of historical inquiries, solutions, and outcomes 106. In some embodiments, the database of historical inquiries, solutions, and outcomes 106 may include a data structure (e.g., a database, an array, a linked list, a record, a hash table, and/or the like) that includes data associated with previously-received inquiries regarding data centers, previously determined solutions to the inquiries, outcomes of implementing the solutions to the inquiries, documents prepared by technical experts, commonly posed problems and solutions within data centers, and/or the like. For example, and as shown in FIG. 1 by an example table 126, the database of historical inquiries, solutions, and outcomes 106 may include a plurality of actions taken with respect to a data center design and, for each action, an associated outcome of implementing the action. Pre-training the model based on the historical data may configure the knowledge base model 120 to be able to make decisions regarding actions that may be taken with respect to data centers and/or data center designs to achieve particular outcomes, such as performance characteristics. In some embodiments, the data in the database of historical inquiries, solutions, and outcomes 106 may be domain-based. For example, for a healthcare medical instrument user, the data may include data center solutions with greater memory capabilities due to the user of streaming applications by the user. As another example, for an automotive user, the data may include data center solutions with greater redundancy and high fidelity during inference (e.g., high availability and throughput) as well as a simulation method to perform verification and validation of the trained models. When training a model for an automotive user, the memory associated with the graphic processing units may be expanded to increase data locality and data transfer. For example, a specialized combination of software and hardware may be required for an automotive data center to increase the user's ability to guarantee performance between simulated hardware and actual hardware in an automotive vehicle.

As shown in block 116, the process flow 100 may include performing supervised training on the pre-trained model to configure the knowledge base model 120 to determine solutions to inquiries regarding data centers. In some embodiments, the knowledge base model 120 may be configured to determine all possible solutions to a given inquiry (e.g., based on the data in the database of rules 102, the database of technical literature 104, and/or the database of historical inquiries, solutions, and outcomes, among other possible sources of data).

Additionally, or alternatively, the supervised training may fine-tune the knowledge base model 120 such that the knowledge base model 120 is configured to determine a set of possible, reasonable solutions to a given inquiry, where the supervisor assists with the fine-tuning such that unreasonable solutions are not provided in response to inquiries. In some embodiments, the knowledge base model 120 may be and/or include a supervised model trained using rule data including rules for configuring data centers, historical solution data including historical configurations of data centers developed for customers based on customer requirements, and historical action data including historical actions performed on data centers and historical outcomes of the historical actions. Additionally, or alternatively, the knowledge base model 120 may be and/or include a language model (e.g., a transformer-based model) designed for information retrieval. In some embodiments, the knowledge base model 120 may be and/or include a pre-trained information retrieval large language model (LLM), and the process flow 100 may include fine tuning and/or training the pre-trained information retrieval LLM using data from one or more of the data structures described herein to configure the knowledge base model 120 to determine solutions to inquiries regarding data centers. The process flow 100 may also include using one or more information retrieval platforms, such as knowledge graphs, similarity searches, embedding searches, and/or the like to determine solutions to inquiries regarding data centers.

The process flow 100 may include additional embodiments, such as any single embodiment or any combination of embodiments described above and/or in connection with one or more other processes described elsewhere herein. Although FIG. 1 shows example blocks of the process flow 100, in some embodiments, the process flow 100 may include additional blocks, fewer blocks, different blocks, or differently arranged blocks than those depicted in FIG. 1. Additionally, or alternatively, two or more of the blocks of the process flow 100 may be performed in parallel and/or simultaneously.

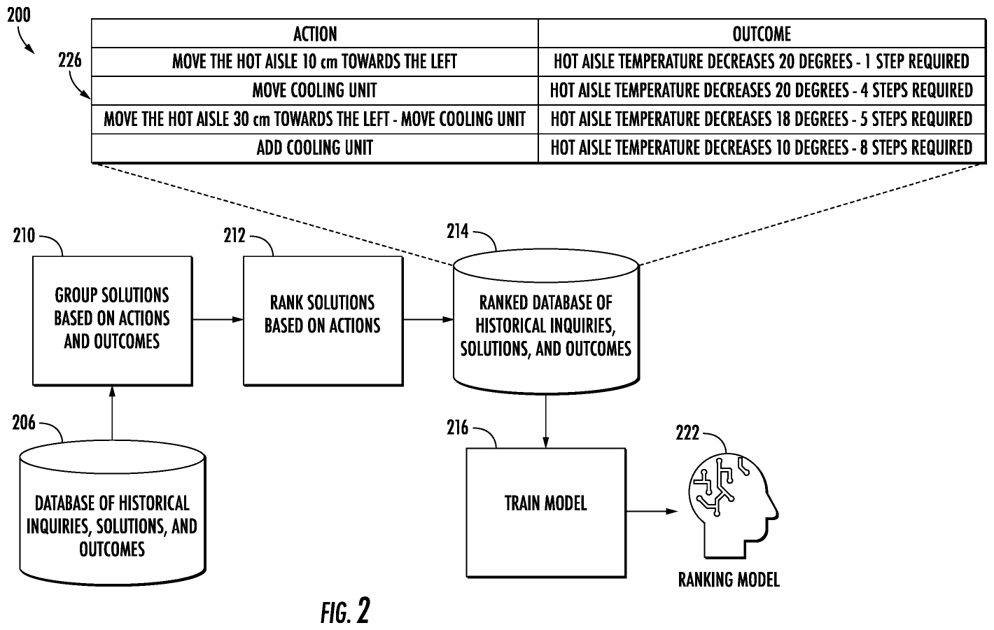

FIG. 2 illustrates a process flow 200 for training a ranking model 222 (e.g., one or more machine learning models), in accordance with an embodiment of the invention. In some embodiments, one or more data center design systems (e.g., similar to the data center design system described herein with respect to FIG. 5), one or more solution determining and ranking platforms (e.g., similar to the solution determining and ranking platform described herein with respect to FIG. 5), and/or the like may perform one or more of the steps of the process flow 200. In some embodiments, the ranking model 222 may be configured (e.g., by the training) to determine rankings for solutions to inquiries regarding data centers (e.g., rankings for solutions determined by the knowledge base model 120).

As shown in block 210, the process flow 200 may include grouping solutions based on actions and outcomes from a database of historical inquiries, solutions, and outcomes 206. In some embodiments, the database of historical inquiries, solutions, and outcomes 206 may be similar to the database of historical inquiries, solutions, and outcomes 106 of FIG. 1 and may include a plurality of actions taken with respect to a data center design and, for each action, an associated outcome of implementing the action. For example, the database of historical inquiries, solutions, and outcomes 206 may include a data structure (e.g., a database, an array, a linked list, a record, a hash table, and/or the like) that includes data associated with previously-received inquiries regarding data centers, previously-determined solutions to the inquiries, and outcomes of implementing the solutions to the inquiries. In this regard, the process flow 200 may include grouping the historical solutions based on the actions taken to implement the historical solutions and grouping the historical solutions based on the outcomes resulting from implementing the historical solutions.

As shown in block 212, the process flow 200 may include ranking the solutions based on the actions. For example, the process flow 200 may include ranking the solutions based on a number of actions or steps required to implement the solutions, where solutions with fewer actions or steps are ranked higher than solutions with more actions or steps. As another example, the process flow 200 may include ranking the solutions based on a difficulty of the actions or steps required to implement the solutions, where solutions with easier or simpler actions or steps are ranked higher than solutions with more difficult or complex actions or steps. In some embodiments, the process flow 200 may include ranking the solutions based on one or more performance metrics, where better-performing solutions are ranked higher than other solutions. The performance metrics may be based on traditional metrics, such as precision, recall, F1 score, similarity, and/or the like. For language-based solutions, the solutions may be ranked based on General Language Understanding Evaluation (GLUE) benchmarks, entropy, and/or the like.

As shown in FIG. 2, the process flow 200 may include generating a ranked database of historical inquiries, solutions, and outcomes 214. In some embodiments, the ranked database of historical inquiries, solutions, and outcomes 214 may include a data structure (e.g., a database, an array, a linked list, a record, a hash table, and/or the like) that includes data associated with previously-received inquiries regarding data centers, previously-determined solutions to the inquiries, and outcomes of implementing the solutions to the inquiries (e.g., data from the database of historical inquiries, solutions, and outcomes 206), where the data is ranked based on the ranking established in block 212. For example, and as shown in FIG. 2 by an example table 226, the ranked database of historical inquiries, solutions, and outcomes 214 may include a plurality of actions taken with respect to a data center design and, for each action, an associated outcome of implementing the action, where the actions are ranked based on the number of steps required to implement the actions.

As shown in block 216, the process flow 200 may include training the ranking model 222 based on data from the ranked database of historical inquiries, solutions, and outcomes 214. Training the model based on the historical data may configure the ranking model 222 to be able to make decisions regarding which solutions generated by the knowledge base model 120 may be preferred by users, have better performance, and/or the like and, therefore, should be presented first to users, when providing the solutions to users' inquiries. In some embodiments, the ranking model 222 may be and/or include a supervised model trained using historical action data including historical actions performed on data centers and historical outcomes of the historical actions.

In some embodiments, the process flow 200 may include training the ranking model 222 using a reinforcement learning from human feedback (RLHF) technique. For example, the process flow 200 may include pretraining a language model, training a reward model using data from one or more of the data structures described herein, and fine-tuning the language model with reinforcement learning. The process flow 200 may include training the reward model to receive a sequence of text and output a scalar reward representative of user preference using data including human feedback indicative of user preference for various sequences of text. The process flow 200 may further include using the trained reward model to fine tune the language model to output user-preferred solutions to users' inquiries. In some embodiments, the ranking model 222 may use one or more algorithms, such as a greedy search algorithm, a beam search algorithm, and/or the like, to determine the best solutions and/or the best n solutions to users' inquiries.

The process flow 200 may include additional embodiments, such as any single embodiment or any combination of embodiments described above and/or in connection with one or more other processes described elsewhere herein. Although FIG. 2 shows example blocks of the process flow 200, in some embodiments, the process flow 200 may include additional blocks, fewer blocks, different blocks, or differently arranged blocks than those depicted in FIG. 2. Additionally, or alternatively, two or more of the blocks of the process flow 200 may be performed in parallel and/or simultaneously.

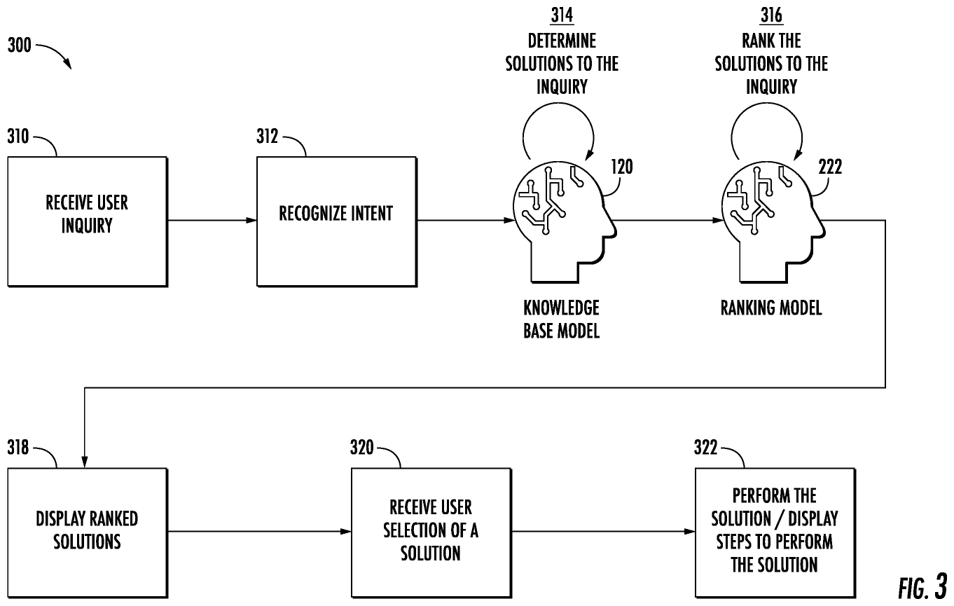

FIG. 3 illustrates a process flow 300 for intelligently responding to a user inquiry regarding a data center, in accordance with an embodiment of the invention. In some embodiments, one or more data center design systems (e.g., similar to the data center design system described herein with respect to FIG. 5), one or more solution determining and ranking platforms (e.g., similar to the solution determining and ranking platform described herein with respect to FIG. 5), and/or the like may perform one or more of the steps of the process flow 300.

As shown in block 310, the process flow 300 may include receiving a user inquiry. In some embodiments, the process flow 300 may include receiving a user inquiry from a user device (e.g., as a submission to a website, via email, via text message, via voicemail, and/or the like). For example, the user inquiry may include a question about a data center, a request to change a configuration of a data center, and/or the like. In some embodiments, the user inquiry may be a text-based inquiry, an audio inquiry, and/or the like.

As shown in block 312, the process flow 300 may include recognizing the intent of the user inquiry. In some embodiments, the user inquiry may be in the form of natural language, and the process flow 300 may include analyzing the user inquiry using a natural language processor to determine keywords and/or an intent of the user inquiry. For example, a user inquiry may include text and/or audio including, “Add more cooling on rack number 12.” The process flow 300 may include parsing the user inquiry to determine that the user inquiry intends to modify cooling on rack number 12 and/or that keywords associated with the user inquiry are “modify,” “cooling,” and “rack number 12.”

As shown in step 314, the process flow 300 may include determining solutions to the user inquiry. In some embodiments, and as shown in FIG. 3, the process flow 300 may include using the knowledge base model 120 to determine solutions to the user inquiry. Using the example of the user inquiry including text and/or audio including, “Add more cooling on rack number 12,” the process flow 300 may include providing the determined intent and/or the keywords associated with the user inquiry (e.g., “modify,” “cooling,” and “rack number 12”) to the knowledge base model 120. The knowledge base model 120 may then determine all possible and/or all reasonable, possible solutions to the user inquiry.

As shown in step 316, the process flow 300 may include ranking the solutions to the user inquiry. In some embodiments, and as shown in FIG. 3, the process flow 300 may include using the ranking model 222 to rank the solutions to the user inquiry. For example, the process flow 300 may include providing the solutions determined by the knowledge base model 120 to the ranking model 222 and using the knowledge base model 120 to rank the solutions. In some embodiments, and as noted with respect to FIG. 2, the ranking model 222 may be configured to rank the solutions based on the number of actions or steps required to implement the solutions, where solutions with fewer actions or steps are ranked higher than solutions with more actions or steps. Additionally, or alternatively, the ranking model 222 may be configured to rank the solutions based on a difficulty of the actions or steps required to implement the solutions, where solutions with easier or simpler actions or steps are ranked higher than solutions with more difficult or complex actions or steps. In some embodiments, the ranking model 222 may be configured to rank the solutions based on one or more performance metrics, where better performing solutions are ranked higher than other solutions. For example, the ranking model 222 may be configured to rank the solutions based on the amount of cooling achieved by a given solution, the amount of power used to achieve the cooling in the given solution, or a combination of the amount of cooling and the amount of power.

As shown in block 318, the process flow 300 may include displaying the ranked solutions. In some embodiments, the process flow 300 may include causing a display device (e.g., a monitor, screen, or display associated with the user device, a data center design system, and/or the like) to display the ranked solutions to a user. For example, the ranked solutions may be displayed via generation of a graphical user interface including a table that presents the highest ranked, most preferred, simplest, easiest, and/or the like solution first in the table.

As shown in block 320, the process flow 300 may include receiving a user selection of a solution. In some embodiments, the user may select a solution from the displayed, ranked solutions via an input device (e.g., of a user device, a data center design system, and/or the like). The input device may be, for example, a keyboard, mouse, touch screen, joystick, or other component configured to receive input from the user. For example, when the ranked solutions are displayed via a graphical user interface, the process flow 300 may include receiving the user selection of the solution via the user's interaction with the graphical user interface (such as by the user touching a portion of the graphical user interface using a touch screen input device).

As shown in block 322, the process flow 300 may include performing the solution or displaying the steps to perform the solution. In some embodiments, the solution may be performed automatically or the steps to perform the solution may be displayed automatically in response to the user's selection of the solution. Using the example of the user inquiry including text and/or audio including, “Add more cooling on rack number 12,” the user-selected solution may be to move rack number 12 ten centimeters towards the right, and the process flow 300 may include, in response to the user selection, commanding an autonomous robot within a data center to move rack number 12 ten centimeters towards the right.

As another example, the process flow 300 may include displaying steps to perform the user-selected solution such that the user may perform the steps to implement the solution or provide the steps to a technician. In some embodiments, the process flow 300 may include displaying or causing a display device to display virtual performances of each step of the steps in a three-dimensional representation of the data center. For example, the virtual performance may demonstrate to the user how to enter the data center, where to go within the data center, which equipment to manipulate, which components of equipment to manipulate, how to manipulate the equipment and/or the components, and/or the like. As another example, the three-dimensional representation of the data center may be presented in a metaverse and may include details of the data center and its components, such as positioning and number of racks, data cabling, power cabling, cooling systems, and/or the like.

In some embodiments, the process flow 300 may include receiving another inquiry from the user regarding the ranked solutions. For example, the user may dislike the floorplan or layout of a design for the data center and may request additional options for the floorplan. In such embodiments, the process flow 300 may include running a plurality of simulations (e.g., using the knowledge base model 120 and/or the ranking model 222) on multiple hyperparameters and then presenting the options to the user.

The process flow 300 may include additional embodiments, such as any single embodiment or any combination of embodiments described above and/or in connection with one or more other processes described elsewhere herein. Although FIG. 3 shows example blocks of the process flow 300, in some embodiments, the process flow 300 may include additional blocks, fewer blocks, different blocks, or differently arranged blocks than those depicted in FIG. 3. Additionally, or alternatively, two or more of the blocks of the process flow 300 may be performed in parallel and/or simultaneously.

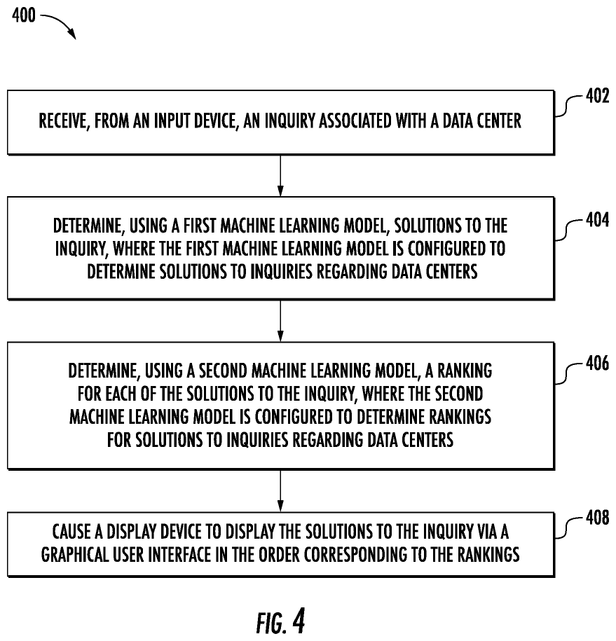

FIG. 4 illustrates another process flow 400 for intelligently responding to a user inquiry regarding a data center, in accordance with an embodiment of the invention. In some embodiments, one or more data center design systems (e.g., similar to the data center design system described herein with respect to FIG. 5), one or more solution determining and ranking platforms (e.g., similar to the solution determining and ranking platform described herein with respect to FIG. 5), and/or the like may perform one or more of the steps of the process flow 400.

As shown in block 402, the process flow 400 may include receiving, from an input device, an inquiry associated with a data center. In some embodiments, the input device may be an input device of a user device, and the process flow 400 may include receiving the inquiry from the input device of the user device. For example, a user may use the input device to enter the inquiry in a user interface generated by software that is executed on the user device, in a user interface of a website, via a telephone call with a voice-based interactive system, and/or the like. Additionally, or alternatively, the input device may be an input device of a data center design system.

As shown in block 404, the process flow 400 may include determining, using a first machine learning model, solutions to the inquiry, where the first machine learning model is configured to determine solutions to inquiries regarding data centers. In some embodiments, the first machine learning model may be similar to the knowledge base model 120 described herein with respect to FIGS. 1-3. For example, the first machine learning model may be trained to determine solutions to inquiries regarding data centers in a manner similar to that described herein with respect to the process flow 100 of FIG. 1.

As shown in block 406, the process flow 400 may include determining, using a second machine learning model, a ranking for each of the solutions to the inquiry, where the second machine learning model is configured to determine rankings for solutions to inquiries regarding data centers. In some embodiments, the second machine learning model may be similar to the ranking model 222 described herein with respect to FIGS. 2-3. For example, the second machine learning model may be trained to determine rankings for solutions to inquiries regarding data centers in a manner similar to that described herein with respect to the process flow 200 of FIG. 2.

In some embodiments, the process flow 400 may include adjusting a graphical user interface to include the solutions to the inquiry in an order corresponding to the rankings. Additionally, or alternatively, the graphical user interface may be displayed on a display device of the user device and/or the data center design system. In some embodiments, the graphical user interface may include the solutions in a table, a menu, a listing, a plurality of icons, and/or the like.

As shown in block 408, the process flow 400 may include causing a display device to display the solutions to the inquiry via a graphical user interface in the order corresponding to the rankings. For example, the process flow 400 may include causing a display device of the user device and/or the data center design system to display the graphical user interface. The graphical user interface may include a text input space, one or more buttons to toggle a capability of receiving audio input (e.g., speech input), one or more sections for displaying video output (e.g., demonstrating a solution), and/or the like.

In some embodiments, the process flow 400 may include receiving, from the input device, selection of a first solution of the solutions and causing, in response to receiving the selection of the first solution, the display device to display a virtual performance of the first solution in a three-dimensional representation of the data center. For example, the virtual performance may demonstrate to the user how to enter the data center, where to go within the data center, which equipment to manipulate, which components of equipment to manipulate, how to manipulate the equipment and/or the components, and/or the like. As another example, the three-dimensional representation of the data center may be presented in a metaverse and may include details of the data center and its components, such as positioning and number of racks, data cabling, power cabling, cooling systems, and/or the like.

In some embodiments, the inquiry may include a question about the data center. For example, the inquiry may ask what a data center having particular performance characteristics looks like, how much cabling is in the data center, how many cooling units are in the data center, a size of the data center, and/or the like.

In some embodiments, the inquiry may include a request to change a configuration of an existing data center. For example, the inquiry may include a request to move one or more racks in the data center, move one or more hot aisles and/or cold aisles, re-route cooling, cabling, and/or power, increase or decrease cooling, increase or decrease data cabling, and/or the like.

In such embodiments, the process flow 400 may include determining one or more processes for changing the configuration of the data center; determining, for each process of the one or more processes, a number of steps required to perform the respective process; and adjusting the graphical user interface to include the one or more processes in the order based on the number of steps required to perform each process of the one or more processes. Additionally, or alternatively, the process flow 400 may include receiving (e.g., with the input device) selection of a first process of the one or more processes, where the first process includes a series of steps, and causing, in response to receiving the selection of the first process, the display device to display virtual performances of each step in the series of steps in a three-dimensional representation of the data center.

For example, the inquiry may include a request to add cooling to a rack in the data center, and the process flow 400 may include determining one or more processes for adding cooling to the rack in the data center. The process flow 400 may further include determining, for each process of the one or more processes, a number of steps required to perform the respective process and a cost associated with the respective process. The process flow 400 may further include adjusting the graphical user interface to include the one or more processes in the order based on a combined rating based on the number of steps required to perform each process and the cost associated with each process.

As another example, the inquiry may include a request to move a hot aisle of the data center a user-specified distance in a direction, and the process flow 400 may include determining one or more processes for moving the hot aisle the user-specified distance in the direction within the data center. The process flow 400 may further include determining, for each process of the one or more processes, the number of steps required to perform the respective process and a cost associated with the respective process. The process flow 400 may further include adjusting the graphical user interface to include the one or more processes in the order according to a combined rating based on the number of steps required to perform each process and the cost associated with each process.

In some embodiments, the process flow 400 may include, before determining the solutions to the inquiry, identifying keywords in the inquiry and determining, based on the identified keywords, an intent of the inquiry. For example, the process flow 400 may include using a natural language processor to identify keywords in the inquiry and determine an intent of the inquiry. In such embodiments, the process flow 400 may include determining the solutions to the inquiry based on the identified keywords and the intent of the inquiry.

In some embodiments, the inquiry may include performance characteristics, and the process flow 400 may include determining configurations of equipment in the data center having the performance characteristics. The process flow 400 may also include determining, for each configuration of the configurations, a preference rating for the respective configuration based on historical user preference data. Furthermore, the process flow 400 may also include adjusting the graphical user interface to include the configurations in the order based on the preference rating for each configuration of the configurations.

In such embodiments, the process flow 400 may further include, after causing the display device to display the graphical user interface, receiving, from the input device, a selection of a first configuration of the configurations and another inquiry. For example, the other inquiry may include a size of the data center, a request for a materials list and associated floor plan implementing the first configuration, and/or the like. The process flow 400 may further include determining, using the first machine learning model, a plurality of materials lists and associated floor plans implementing the first configuration in the data center corresponding to the size.

In such embodiments, the process flow 400 may further include determining, using the second machine learning model and for each materials list and associated floor plan of the plurality of materials lists and associated floor plans, a preference rating for the respective materials list and associated floor plan. For example, the preference ratings may be based on data in a data structure, such as the database of historical inquiries, solutions, and outcomes 206, the ranked database of historical inquiries, solutions, and outcomes 214, and/or the like. The process flow 400 may further include causing the display device to display the plurality of materials lists and associated floor plans in order based on the preference rating for each respective materials list and associated floor plan.

In such embodiments, the process flow 400 may further include, after causing the display device to display the plurality of materials lists and associated floor plans, receiving, from the input device, a second selection of a first materials list and an associated first floor plan of the plurality of materials lists and associated floor plans. The process flow 400 may further include causing, in response to receiving the second selection, the display device to display a three-dimensional representation of the data center having the first floor plan.

In some embodiments, the process flow 400 may include providing retraining data to another system for retraining the first machine learning model and/or the second machine learning model, where the retraining data includes inquiries received from the input device and outcomes associated with the inquiries. Additionally, or alternatively, the process flow 400 may include retraining the first machine learning model and/or the second machine learning model using retraining data including inquiries received from the input device and outcomes associated with the inquiries.

In some embodiments, the inquiry may include a request to design a data center to have selected performance characteristics, and the process flow 400 may include determining one or more designs for the data center to achieve the selected performance characteristics. The process flow 400 may further include determining, for each design of the one or more designs, a preference rating for the respective design based on historical user preference data and displaying and/or adjusting the graphical user interface to include the one or more designs in the order based on the preference rating for each design of the one or more designs. The process flow 400 may further include receiving selection input from the user selecting a first design of the one or more designs.

In such embodiments, the process flow 400 may include displaying a user-navigable three-dimensional representation of the data center according to the first design and receiving, using the input device, navigation input from the user including navigation commands. The process flow 400 may further include adjusting, in response to receiving the navigation input and using the display device, the displayed user-navigable three-dimensional representation of the data center based on the navigation commands.

In some embodiments, the process flow 400 may include, before determining the solutions to the inquiry using the first machine learning model, analyzing the inquiry to determine whether the inquiry is relevant, appropriate, an attempt to misappropriate information, and/or the like. Based on determining that the inquiry is not relevant, inappropriate, or an attempt to misappropriate information, the process flow 400 may include preventing the first machine learning model and the second machine learning model from processing the inquiry. For example, the process flow 400 may include using guardrails or masking between user input and the machine learning models to secure the machine learning models from drifting off topic, developing inappropriate responses, being attacked, being misused, and/or the like.

Additionally, or alternatively, the process flow 400 may include, before providing the solutions to the inquiry to the user, analyzing the solutions to determine whether the solutions are relevant, appropriate, contain confidential information, and/or the like. Based on determining that the inquiry is not relevant, inappropriate, or contains confidential information, the process flow 400 may include preventing the solutions from being provided to the user. For example, the process flow 400 may include using guardrails or masking between the machine learning models and the user to prevent the machine learning models from providing irrelevant information, inappropriate responses, confidential information, and/or the like. Such guardrails or masking may be bidirectional and provide a filter between the user and the machine learning models to maintain security of the machine learning models and associated databases.

The process flow 400 may include additional embodiments, such as any single embodiment or any combination of embodiments described above and/or in connection with one or more other processes described elsewhere herein. Although FIG. 4 shows example blocks of the process flow 400, in some embodiments, the process flow 400 may include additional blocks, fewer blocks, different blocks, or differently arranged blocks than those depicted in FIG. 4. Additionally, or alternatively, two or more of the blocks of process flow 400 may be performed in parallel and/or simultaneously.

FIG. 5 illustrates a system environment 500 for intelligently designing and reconfiguring data centers, in accordance with an embodiment of the invention. As shown in FIG. 5, the system environment 500 may include a data center design system 510, a user device 520, one or more data structures 530, a solution determining and ranking platform 540, a cloud computing environment 550 with computing resources 555, and a network 560. Devices of the environment 500 may interconnect via wired connections, wireless connections, or a combination of wired and wireless connections.

In some embodiments, the data center design system 510 may include one or more devices capable of receiving, generating, storing, processing, displaying and/or causing display of, determining, and/or providing inquiries regarding data centers, solutions to inquiries regarding data centers, graphical user interfaces regarding inquiries and solutions, virtual performances of solutions, three-dimensional representations of data centers, and/or the like. Additionally, or alternatively, the data center design system 510 may include one or more devices capable of training and/or retraining one or more machine learning models.

In some embodiments, the user device 520 may include one or more devices capable of receiving, generating, storing, processing, displaying and/or causing display of, determining, and/or providing inquiries regarding data centers, solutions to inquiries regarding data centers, graphical user interfaces regarding inquiries and solutions, virtual performances of solutions, three-dimensional representations of data centers, and/or the like. Additionally, or alternatively, the user device 520 may include one or more devices capable of training and/or retraining one or more machine learning models. For example, the user device 520 may include a communication and/or computing device, such as a mobile phone (e.g., a smart phone), a laptop computer, a tablet computer, a handheld computer, a gaming device, a wearable communication device (e.g., a smart wristwatch, a pair of smart eyeglasses, and/or the like), or a similar type of device. The user device 520 may be associated with a user that has an established relationship with an entity or organization associated with the data center design system 510 and/or the solution determining and ranking platform 540.

The one or more data structures 530 may include any type of data structure (e.g., a database, an array, a linked list, a record, a hash table, and/or the like) for storing data associated with data centers. In some embodiments, the one or more data structures 530 may be maintained on-site with the data center design system 510 and/or the user device 520. Additionally, or alternatively, the one or more data structures 530 may be cloud-based and may be stored remotely from the data center design system 510 and/or the user device 520.

In some embodiments, the solution determining and ranking platform 540 may include one or more computing resources assigned to receive inquiries, determine solutions to inquiries, determine rankings for solutions, adjust graphical user interfaces, cause display devices to generate and/or display graphical user interfaces, generate virtual performances of solutions, generate three-dimensional representations of data centers, train and/or retrain machine learning models, and/or the like, as described herein (e.g., with respect to FIGS. 1-4 and process flows 100, 200, 300, and 400). For example, the solution determining and ranking platform 540 may be a platform implemented by the cloud computing environment 550 that may receive inquiries, determine solutions to inquiries, determine rankings for solutions, generate and/or adjust graphical user interfaces, cause display devices to display graphical user interfaces, generate virtual performances of solutions, generate three-dimensional representations of data centers, train and/or retrain machine learning models, and/or the like. In some embodiments, the solution determining and ranking platform 540 may be implemented by computing resources 555 of the cloud computing environment 550.

The solution determining and ranking platform 540 may include a server device or a group of server devices. In some embodiments, solution determining and ranking platform 540 may be hosted in cloud computing environment 550. Notably, while embodiments described herein describe the solution determining and ranking platform 540 as being hosted in cloud computing environment 550, in some embodiments, the solution determining and ranking platform 540 may be non-cloud-based or may be partially cloud-based.

The cloud computing environment 550 may include an environment that delivers computing as a service, whereby shared resources, services, and/or the like may be provided to other devices, such as the data center design system 510 and/or the user device 520. The cloud computing environment 550 may provide computation, software, data access, storage, and/or other services that do not require end-user knowledge of a physical location and configuration of a system and/or a device that delivers the services. As shown, the cloud computing environment 550 may include the solution determining and ranking platform 540 and the computing resource 555.

The computing resource 555 may include one or more personal computers, workstation computers, server devices, or another type of computation and/or communication device. In some embodiments, the computing resource 555 may host the solution determining and ranking platform 540. The cloud resources may include compute instances executing in the computing resource 555, storage devices provided in the computing resource 555, data transfer devices provided by the computing resource 555, etc. In some embodiments, the computing resource 555 may communicate with other computing resources (not shown) via wired connections, wireless connections, or a combination of wired and wireless connections.

As further shown in FIG. 5, the computing resource 555 may include a group of cloud resources, such as one or more applications (“APPs”) 555-1, one or more virtual machines (“VMs”) 555-2, virtualized storage (“VSs”) 555-3, one or more hypervisors (“HYPs”) 555-4, or the like.

The application 555-1 may include one or more software applications that may be provided to or accessed by devices, such as the data center design system 510 and/or the user device 520. The application 555-1 may eliminate a need to install and execute the software applications on devices, such as the data center design system 510 and/or the user device 520. For example, the application 555-1 may include software associated with the solution determining and ranking platform 540 and/or any other software capable of being provided via the cloud computing environment 550. In some embodiments, one application 555-1 may send and/or receive information to and/or from one or more other applications 555-1 via virtual machine 555-2.

The virtual machine 555-2 may include a software implementation of a machine (e.g., a computer) that executes programs like a physical machine. The virtual machine 555-2 may be either a system virtual machine or a process virtual machine, depending upon use and degree of correspondence to any real machine by the virtual machine 555-2. A system virtual machine may provide a complete system platform that supports execution of a complete operating system (“OS”). A process virtual machine may execute a single program and may support a single process. In some embodiments, the virtual machine 555-2 may execute on behalf of a user (e.g., devices, such as the data center design system 510, the user device 520, the solution determining and ranking platform 540, and/or the like) and may manage infrastructure of the cloud computing environment 550, such as data management, synchronization, or long-duration data transfers.

The virtualized storage 555-3 may include one or more storage systems and/or one or more devices that use virtualization techniques within the storage systems or devices of the computing resource 555. In some embodiments, within the context of a storage system, types of virtualizations may include block virtualization and file virtualization. Block virtualization may refer to abstraction (or separation) of logical storage from physical storage so that the storage system may be accessed without regard to physical storage or heterogeneous structure. The separation may permit administrators of the storage system flexibility in how the administrators manage storage for end users. File virtualization may eliminate dependencies between data accessed at a file level and a location where files are physically stored. This may enable optimization of storage use, server consolidation, and/or performance of non-disruptive file migrations.

The hypervisor 555-4 may provide hardware virtualization techniques that allow multiple operating systems (e.g., “guest operating systems”) to execute concurrently on a host computer, such as the computing resource 555. The hypervisor 555-4 may present a virtual operating platform to the guest operating systems and may manage the execution of the guest operating systems. Multiple instances of a variety of operating systems may share virtualized hardware resources.

The network 560 may include one or more wired and/or wireless networks. For example, the network 560 may include a cellular network (e.g., a long-term evolution (LTE) network, a code division multiple access (CDMA) network, a 3G network, a 4G network, a 5G network, another type of next generation network, etc.), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, or the like, and/or a combination of these or other types of networks.

The number and arrangement of devices and networks shown in FIG. 5 are provided as one or more examples. In practice, there may be additional devices and/or networks, fewer devices and/or networks, different devices and/or networks, or differently arranged devices and/or networks than those shown in FIG. 5. Furthermore, two or more devices shown in FIG. 5 may be implemented within a single device, or a single device shown in FIG. 5 may be implemented as multiple, distributed devices. Additionally, or alternatively, a set of devices (e.g., one or more devices) of the environment 500 may perform one or more functions described as being performed by another set of devices of the environment 500.

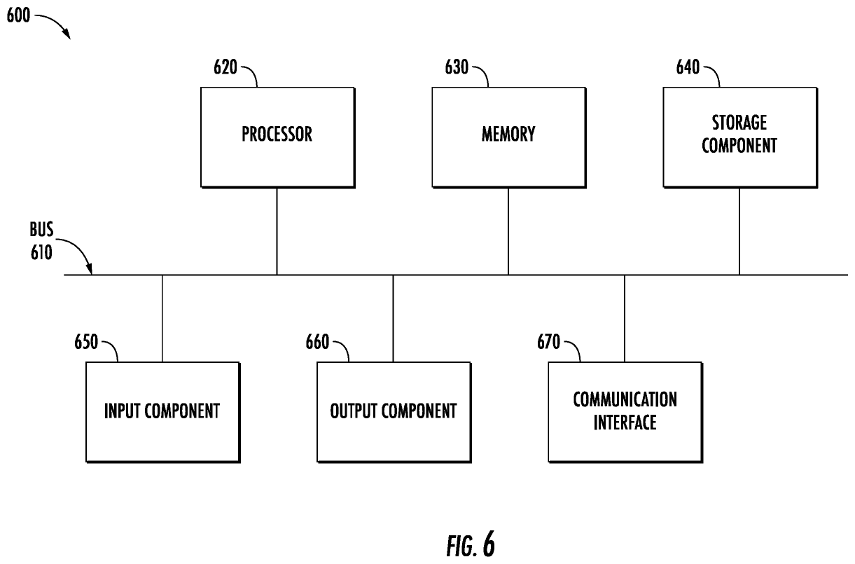

FIG. 6 is a diagram of example components of a device 600. In some embodiments, the device 600 may correspond to the data center design system, the user device, and/or the solution determining and ranking platform described herein with respect to FIGS. 1-5. Additionally, or alternatively, the data center design system, the user device, and/or the solution determining and ranking platform described herein with respect to FIGS. 1-5 may include one or more devices 600 and/or one or more components of the device 600. As shown in FIG. 6, the device 600 may include a bus 610, a processor 620, a memory 630, a storage component 640, an input component 650, an output component 660, and a communication interface 670.

Bus 610 may include a component that permits communication among multiple components of the device 600. The processor 620 may be implemented in hardware, firmware, and/or a combination of hardware and software. The processor 620 may be a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, the processor 620 may include one or more processors capable of being programmed to perform a function. The memory 630 may include a random-access memory (RAM), a read only memory (ROM), and/or another type of dynamic or static storage device (e.g., a flash memory, a magnetic memory, and/or an optical memory) that stores information and/or instructions for use by the processor 620.

The storage component 640 may store information and/or software related to the operation and use of the device 600. For example, the storage component 640 may include a hard disk (e.g., a magnetic disk, an optical disk, and/or a magneto-optic disk), a solid state drive (SSD), a compact disc (CD), a digital versatile disc (DVD), a floppy disk, a cartridge, a magnetic tape, and/or another type of non-transitory computer-readable medium, along with a corresponding drive.

The input component 650 may include a component that permits the device 600 to receive information, such as via user input (e.g., a touch screen display, a keyboard, a keypad, a mouse, a button, a switch, and/or a microphone). Additionally, or alternatively, the input component 650 may include a component for determining location (e.g., a global positioning system (GPS) component) and/or a sensor (e.g., an accelerometer, a gyroscope, an actuator, another type of positional or environmental sensor, and/or the like). The output component 660 may include a component that provides output information from the device 600 (via, e.g., a display, a speaker, a haptic feedback component, an audio or visual indicator, and/or the like).

The communication interface 670 may include a transceiver-like component (e.g., a transceiver, a separate receiver, a separate transmitter, and/or the like) that enables the device 600 to communicate with other devices, such as via a wired connection, a wireless connection, or a combination of wired and wireless connections. The communication interface 670 may permit the device 600 to receive information from another device and/or provide information to another device. For example, the communication interface 670 may include an Ethernet interface, an optical interface, a coaxial interface, an infrared interface, a radio frequency (RF) interface, a universal serial bus (USB) interface, a Wi-Fi interface, a cellular network interface, and/or the like.

The device 600 may perform one or more processes described herein. The device 600 may perform these processes based on the processor 620 executing software instructions stored by a non-transitory computer-readable medium, such as the memory 630 and/or the storage component 640. As used herein, the term “computer-readable medium” refers to a non-transitory memory device. A memory device includes memory space within a single physical storage device or memory space spread across multiple physical storage devices.

Software instructions may be read into the memory 630 and/or the storage component 640 from another computer-readable medium or from another device via the communication interface 670. When executed, software instructions stored in the memory 630 and/or the storage component 640 may cause the processor 620 to perform one or more processes described herein. Additionally, or alternatively, hardware circuitry may be used in place of or in combination with software instructions to perform one or more processes described herein. Thus, embodiments described herein are not limited to any specific combination of hardware circuitry and software.

The number and arrangement of components shown in FIG. 6 are provided as an example. In practice, the device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

As will be appreciated by one of ordinary skill in the art in view of this disclosure, the present invention may include and/or be embodied as an apparatus (including, for example, a system, machine, device, computer program product, and/or the like), as a method (including, for example, a business method, computer-implemented process, and/or the like), or as any combination of the foregoing. Accordingly, embodiments of the present invention may take the form of an entirely business method embodiment, an entirely software embodiment (including firmware, resident software, micro-code, stored procedures in a database, or the like), an entirely hardware embodiment, or an embodiment combining method, software, and hardware aspects that may generally be referred to herein as a “system.” Furthermore, embodiments of the present invention may take the form of a computer program product that includes a computer-readable storage medium having one or more computer-executable program code portions stored therein. As used herein, a processor and/or a processing device, which may include one or more processors, may be “configured to” perform a certain function in a variety of ways, including, for example, by having one or more general-purpose circuits perform the function by executing one or more computer-executable program code portions embodied in a computer-readable medium, and/or by having one or more application-specific circuits perform the function.

It will be understood that any suitable computer-readable medium may be utilized. The computer-readable medium may include, but is not limited to, a non-transitory computer-readable medium and/or a non-transitory storage device, such as a tangible electronic, magnetic, optical, electromagnetic, infrared, and/or semiconductor system, device, and/or other apparatus. For example, in some embodiments, the non-transitory computer-readable medium and/or the non-transitory storage device may include a tangible medium such as a portable computer diskette, a hard disk, a random access memory (RAM), a read-only memory (ROM), an erasable programmable read-only memory (EPROM or Flash memory), a compact disc read-only memory (CD-ROM), and/or some other tangible optical and/or magnetic storage device. In other embodiments of the present invention, however, the computer-readable medium may be transitory, such as, for example, a propagation signal including computer-executable program code portions embodied therein.

One or more computer-executable program code portions for carrying out operations of the present invention may include object-oriented, scripted, and/or unscripted programming languages, such as, for example, Java, Perl, Smalltalk, C++, SAS, SQL, Python, Objective C, JavaScript, and/or the like. In some embodiments, the one or more computer-executable program code portions for carrying out operations of embodiments of the present invention are written in conventional procedural programming languages, such as the “C” programming languages and/or similar programming languages. The computer program code may alternatively or additionally be written in one or more multi-paradigm programming languages, such as, for example, F#.

Some embodiments of the present invention are described herein with reference to flowchart illustrations and/or block diagrams of apparatus and/or methods. It will be understood that each block included in the flowchart illustrations and/or block diagrams, and/or combinations of blocks included in the flowchart illustrations and/or block diagrams, may be implemented by one or more computer-executable program code portions. These one or more computer-executable program code portions may be provided to a processor of a general purpose computer, special purpose computer, and/or some other programmable data processing apparatus in order to produce a particular machine, such that the one or more computer-executable program code portions, which execute via the processor of the computer and/or other programmable data processing apparatus, create mechanisms for implementing the steps and/or functions represented by the flowchart(s) and/or block diagram block(s).

The one or more computer-executable program code portions may be stored in a transitory and/or non-transitory computer-readable medium (e.g., a memory) that may direct, instruct, and/or cause a computer and/or other programmable data processing apparatus to function in a particular manner, such that the computer-executable program code portions stored in the computer-readable medium produce an article of manufacture including instruction mechanisms which implement the steps and/or functions specified in the flowchart(s) and/or block diagram block(s).

The one or more computer-executable program code portions may also be loaded onto a computer and/or other programmable data processing apparatus to cause a series of operational steps to be performed on the computer and/or other programmable apparatus. In some embodiments, this produces a computer-implemented process such that the one or more computer-executable program code portions which execute on the computer and/or other programmable apparatus provide operational steps to implement the steps specified in the flowchart(s) and/or the functions specified in the block diagram block(s). Alternatively, computer-implemented steps may be combined with, and/or replaced with, operator-and/or human-implemented steps in order to carry out an embodiment of the present invention.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other changes, combinations, omissions, modifications, and substitutions, in addition to those set forth in the above paragraphs, are possible. Those skilled in the art will appreciate that various adaptations, modifications, and combinations of the just described embodiments may be configured without departing from the scope and spirit of the invention. Therefore, it is to be understood that, within the scope of the appended claims, the invention may be practiced other than as specifically described herein.

What is claimed is:

1. A system for designing a data center, the system comprising:
a display device configured to display a graphical user interface;
an input device configured to receive user input;
a first machine learning model configured to determine solutions to inquiries regarding data centers;
a second machine learning model configured to determine rankings for solutions to inquiries regarding data centers;
a non-transitory storage device comprising computer executable program code; and
a processor in communication with the display device, the input device, the first machine learning model, the second machine learning model, and the non-transitory storage device, wherein the computer-executable program code comprises instructions configured to cause the processor to perform operations comprising:
receive, from the input device, an inquiry associated with a data center based on the user input;
determine, using the first machine learning model, solutions to the inquiry;
determine, using the second machine learning model, a ranking for each of the solutions to the inquiry; and
cause the display device to display the solutions to the inquiry via the graphical user interface in an order corresponding to the rankings.

2. The system of claim 1, wherein the computer-executable program code comprises instructions configured to cause the processor to:
receive, from the input device, selection of a first solution of the solutions; and
cause, in response to receiving the selection of the first solution, the display device to display a virtual performance of the first solution in a three-dimensional representation of the data center.

3. The system of claim 1, wherein the inquiry comprises a request to change a configuration of the data center.

4. The system of claim 3, wherein the computer-executable program code comprises instructions configured to cause the processor to:
in determining the solutions to the inquiry, determine one or more processes for changing the configuration of the data center;
in determining the rankings for the solutions to the inquiry, determine, for each process of the one or more processes, a number of steps required to perform the respective process; and
adjust the graphical user interface to include the one or more processes in the order based on the number of steps required to perform each process of the one or more processes.

5. The system of claim 4, wherein the computer-executable program code comprises instructions configured to cause the processor to:
receive, from the input device, selection of a first process of the one or more processes, wherein the first process comprises a series of steps; and
cause, in response to receiving the selection of the first process, the display device to display virtual performances of each step in the series of steps in a three-dimensional representation of the data center.

6. The system of claim 1, wherein the computer-executable program code comprises instructions configured to cause the processor to:
before determining the solutions to the inquiry:
identify keywords in the inquiry; and
determine, based on the identified keywords, an intent of the inquiry; and
in determining the solutions to the inquiry, determine the solutions to the inquiry based on the identified keywords and the intent of the inquiry.

7. The system of claim 1, wherein the inquiry comprises performance characteristics, and wherein the computer-executable program code comprises instructions configured to cause the processor to:
in determining the solutions to the inquiry, determine configurations of equipment in the data center having the performance characteristics;
in determining the rankings for the solutions to the inquiry, determine, for each configuration of the configurations, a preference rating for the respective configuration based on historical user preference data; and
in causing the display device to display the solutions to the inquiry, cause the display device to display the configurations in the order based on the preference rating for each configuration of the configurations.

8. The system of claim 7, wherein the inquiry is a first inquiry, and wherein the computer-executable program code comprises instructions configured to cause the processor to:
after causing the display device to display the graphical user interface, receive, from the input device, a selection of a first configuration of the configurations and a second inquiry comprising (i) a size of the data center and (ii) a request for a materials list and associated floor plan implementing the first configuration;
determine, using the first machine learning model, a plurality of materials lists and associated floor plans implementing the first configuration in the data center corresponding to the size;
determine, using the second machine learning model and for each materials list and associated floor plan of the plurality of materials lists and associated floor plans, a preference rating for the respective materials list and associated floor plan; and
cause the display device to display the plurality of materials lists and associated floor plans in another order based on the preference rating for each respective materials list and associated floor plan.

9. The system of claim 1, wherein the first machine learning model is a supervised model trained using rule data comprising rules for configuring data centers, historical solution data comprising historical configurations of data centers developed for customers based on customer requirements, and historical action data comprising historical actions performed on data centers and historical outcomes of the historical actions; and
wherein the computer-executable program code comprises instructions configured to cause the processor to provide retraining data to another system for retraining the first machine learning model, wherein the retraining data comprises inquiries received from the input device and outcomes associated with the inquiries.

10. The system of claim 1, wherein the second machine learning model is a supervised model trained using historical action data comprising historical actions performed on data centers and historical outcomes of the historical actions; and
wherein the computer-executable program code comprises instructions configured to cause the processor to provide retraining data to another system for retraining the second machine learning model, wherein the retraining data comprises inquiries received from the input device and outcomes associated with the inquiries.

11. A computer program product for designing a data center, the computer program product comprising a non-transitory computer-readable medium comprising code that, when executed by a first apparatus, causes the first apparatus to:
receive, using an input device of the first apparatus, input from a user comprising an inquiry associated with a data center;
determine, using a first machine learning model, solutions to the inquiry, wherein the first machine learning model is configured to determine solutions to inquiries regarding data centers;
determine, using a second machine learning model, rankings for the solutions to the inquiry by determining for each solution of the solutions a respective ranking, wherein the second machine learning model is configured to determine rankings for solutions to inquiries regarding data centers;
display, using a display device of the first apparatus, a graphical user interface including the solutions to the inquiry in an order corresponding to the rankings;
receive, using the input device, input from the user selecting a first solution of the solutions; and
display, in response to receiving the selection of the first solution and using the display device, a virtual performance of the first solution in a three-dimensional representation of the data center.

12. The computer program product of claim 11, wherein the inquiry comprises at least one of a question about the data center or a command to change a configuration of the data center.

13. The computer program product of claim 11, wherein the inquiry comprises a request to add cooling to a rack in the data center, and wherein the non-transitory computer-readable medium comprises code that, when executed by the first apparatus, causes the first apparatus to:
in determining the solutions to the inquiry, determine one or more processes for adding cooling to the rack in the data center;
in determining the rankings for the solutions to the inquiry, determine, for each process of the one or more processes, a number of steps required to perform the respective process and a cost associated with the respective process; and
adjust the graphical user interface to comprise the one or more processes in the order based on a combined rating based on the number of steps required to perform each process and the cost associated with each process.

14. The computer program product of claim 11, wherein the inquiry comprises a request to move a hot aisle of the data center a user-specified distance in a direction, and wherein the non-transitory computer-readable medium comprises code that, when executed by the first apparatus, causes the first apparatus to:
in determining the solutions to the inquiry, determine one or more processes for moving the hot aisle the user-specified distance in the direction within the data center;
in determining the rankings for the solutions to the inquiry, determine, for each process of the one or more processes, a number of steps required to perform the respective process and a cost associated with the respective process; and
adjust the graphical user interface to comprise the one or more processes in the order based on a combined rating based on the number of steps required to perform each process and the cost associated with each process.

15. The computer program product of claim 11, wherein the inquiry comprises a request to design the data center to have user-specified performance characteristics, and wherein the non- transitory computer-readable medium comprises code that, when executed by the first apparatus, causes the first apparatus to:
in determining the solutions to the inquiry, determine one or more designs for the data center to achieve the selected performance characteristics;
in determining the rankings for the solutions to the inquiry, determine, for each design of the one or more designs, a preference rating for the respective design based on historical user preference data;
adjust the graphical user interface to comprise the one or more designs in the order based on the preference rating for each design of the one or more designs;
in displaying the virtual performance of the first solution in a three-dimensional representation of the data center, display a user-navigable three-dimensional representation of the data center;
receive, using the input device, navigation input from the user comprising navigation commands; and
adjust, in response to receiving the navigation input and using the display device, the displayed user-navigable three-dimensional representation of the data center based on the navigation commands.

16. A method for designing a data center, the method comprising:
receiving, using an input device, input from a user comprising a request to design a data center having selected performance characteristics;
determining, using a first machine learning model, one or more designs for the data center to achieve the selected performance characteristics, wherein the first machine learning model is configured to determine solutions to inquiries regarding data centers;
determining, using a second machine learning model and for each design of the one or more designs, a preference rating for the respective design based on historical user preference data;
displaying, using a display device, the one or more designs in order of the preference rating for each design of the one or more designs;
receiving, using the input device, selection input from the user selecting a first design of the one or more designs;
displaying, using the display device and in response to receiving the selection input, a user-navigable three-dimensional representation of the data center configured according to the first design;
receiving, using the input device, navigation input from the user comprising navigation commands; and
adjusting, in response to receiving the navigation input, the displayed user-navigable three-dimensional representation of the data center based on the navigation commands.

17. The method of claim 16, comprising, after receiving the selection input selecting the first design:
receiving, using the input device, inquiry input from the user comprising a request for a materials list implementing the first design;
determining, using the first machine learning model, a plurality of materials lists implementing the first design;
determining, using the second machine learning model and for each materials list of the plurality of materials lists, a preference rating for the respective materials list; and
displaying, using the display device, the plurality of materials lists in order of the preference rating for each materials list of the plurality of materials lists.

18. The method of claim 16, comprising:
receiving, from the input device, an inquiry associated with the data center;
determining, using the first machine learning model, solutions to the inquiry;
determining, using the second machine learning model, a ranking for each of the solutions to the inquiry; and
causing the display device to display the solutions to the inquiry via a graphical user interface in an order corresponding to the rankings.

19. The method of claim 18, comprising:
receiving, from the input device, selection of a first solution of the solutions; and
causing, in response to receiving the selection of the first solution, the display device to display a virtual performance of the first solution in the user-navigable three-dimensional representation of the data center.

20. The method of claim 18, comprising:
in determining the solutions to the inquiry, determining configurations of equipment in the data center having the performance characteristics;
in determining the rankings for the solutions to the inquiry, determining, for each configuration of the configurations, a preference rating for the respective configuration based on historical user preference data; and
in causing the display device to display the solutions to the inquiry, causing the display device to display the configurations in the order based on the preference rating for each configuration of the configurations.
